(19) United States
(12) Patent Application Publication
(10) Pub. No.: US 2012/0001182 A1
(43) Pub. Date: Jan. 5, 2012

(54) ORGANIC LIGHT-EMITTING DISPLAY DEVICE AND METHOD OF MANUFACTURING THE SAME

(75) Inventors: Jong-Hyun Choi, Yongin-City (KR); Dae-Woo Lee, Yongin-City (KR)

(73) Assignee: Samsung Mobile Display Co., Ltd., Yongin-City (KR)

(21) Appl. No.: 13/041,181

(22) Filed: Mar. 4, 2011

(30) Foreign Application Priority Data
Jul. 2, 2010 (KR) 10-2010-0063869

(51) Int. Cl. H01L 33/16; B82Y 99/00

(52) U.S. Cl. 257/59; 257/72; 438/34; 977/755; 257/E33.004

(57) ABSTRACT

An organic light-emitting display device that may be easily manufactured and has an excellent display quality, the organic light-emitting display device including: an active layer of a thin-film transistor (TFT) formed on a substrate and including a semiconductor material; a lower electrode of a capacitor formed on the substrate and including a semiconductor material in which impurity ions are doped; a first insulating layer formed on the substrate so as to cover the active layer and the lower electrode; a gate electrode of the TFT formed on the first insulating layer and including a first gate electrode including silver (Ag) or an Ag alloy, a second gate electrode including a transparent conductive material, and a third gate electrode including metal that are sequentially stacked in the order stated; a plurality of pixel electrodes formed on the first insulating layer and including a first pixel electrode including Ag or an Ag alloy and a second pixel electrode including a transparent conductive material that are sequentially stacked in the order stated; an upper electrode of the capacitor formed on the first insulating layer and including a first upper electrode including Ag or an Ag alloy and a second upper electrode including a transparent conductive material that are sequentially stacked in the order stated; source and drain electrodes of the TFT electrically connected to the active layer; an organic layer disposed on the pixel electrode and including an organic emission layer; and an opposite electrode disposed facing each of the pixel electrodes while the organic layer is interposed between the opposite electrode and each of the pixel electrodes, and a method of manufacturing the organic light-emitting display device.

### CROSS-REFERENCE TO RELATED APPLICATIONS

This application claims the benefit of Korean Patent Application No. 10-2010-0063869, filed on Jul. 2, 2010, in the Korean Intellectual Property Office, the disclosure of which is incorporated herein in its entirety by reference.

### BACKGROUND

1. Field

The present embodiments relate to an organic light-emitting display device and a method of manufacturing the same, and more particularly, to an organic light-emitting display device that may be easily manufactured and has an excellent display quality, and a method of manufacturing the same.

2. Description of the Related Technology

Organic light-emitting display devices have drawn attention as next generation display devices because their weight and thickness may be reduced and they have superior characteristics such as wide viewing angles, short response times, and low power consumption.

In an organic light-emitting display device that realizes full color, an optical resonant structure, in which the optical length of each wavelength generated in an organic light-emitting layer of each of the pixels of different colors, such as red, green, and blue pixels, varies, is employed.

### SUMMARY

The present embodiments provide an organic light-emitting display device that may be easily manufactured on a large scale and has an excellent display quality, and a method of manufacturing the same. According to an aspect of the present embodiments, there is provided an organic light-emitting display device including: an active layer of a thin-film transistor (TFT) formed on a substrate and including a semiconductor material; a lower electrode of a capacitor formed on the substrate and including a semiconductor material in which impurity ions are doped; a first insulating layer formed on the substrate so as to cover the active layer and the lower electrode; a gate electrode of the TFT formed on the first insulating layer and including a first gate electrode including silver (Ag) or an Ag alloy, a second gate electrode including a transparent conductive material, and a third gate electrode including metal that are sequentially stacked in the order stated; a plurality of pixel electrodes formed on the first insulating layer and including a first pixel electrode including Ag or an Ag alloy and a second pixel electrode including a transparent conductive material that are sequentially stacked in the order stated; an upper electrode of the capacitor formed on the first insulating layer and including a first upper electrode including Ag or an Ag alloy and a second upper electrode including a transparent conductive material that are sequentially stacked in the order stated; source and drain electrodes of the TFT electrically connected to the active layer; an organic layer disposed on the pixel electrode and including an organic emission layer; and an opposite electrode disposed facing each of the pixel electrodes while the organic layer is interposed between the opposite electrode and each of the pixel electrodes.

The first gate electrode, the first pixel electrode, and the first upper electrode may include a structure in which a first metal layer, a transparent conductive layer, and a second metal layer are sequentially stacked in the order stated, and at least one of the first metal layer and the second metal layer may include Ag or an Ag alloy.

Thicknesses of the first metal layer and the second metal layer may be respectively between about 20 Å and 130 Å.

A sum of the thicknesses of the first metal layer and the second metal layer may be between about 100 Å and 200 Å.

The second gate electrode, the second pixel electrode, and the second upper electrode may include at least one material selected from the group consisting of an indium tin oxide (ITO), an indium zinc oxide (IZO), a zinc oxide (ZnO), an indium oxide (In₂O₃), an indium gallium oxide (IGO), and an aluminum zinc oxide (AZO).

The organic light-emitting display device may further include: a third pixel electrode stacked on the second pixel electrode and including metal; and a second insulating layer formed on the first insulating layer so as to cover the third pixel electrode and the gate electrode and including a first opening for exposing portions of the second pixel electrode, a second opening for exposing portions of the third pixel electrode, and a third opening for exposing the second upper electrode, wherein the source and drain electrodes are formed on the second insulating layer, and one of the source and drain electrodes contacts the third pixel electrode through the second opening.

The third pixel electrode and the third gate electrode may include the same metal, and the metal may include at least one metal selected from the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The third pixel electrode and the third gate electrode may include multiple metal layers.

The first pixel electrode may be a semi-transmission mirror through which some of light emitted from the organic emission layer transmits or from which some of light emitted from the organic emission layer is reflected.

The opposite electrode may be used to reflect light emitted from the organic emission layer.

An end of the first pixel electrode and an end of the second pixel electrode may have an identical etching surface.

The organic light-emitting display device may further include a third insulating layer formed on the second insulating layer, wherein the third insulating layer includes a fourth opening for exposing portions of the second pixel electrode exposed through the first opening and covers the source and drain electrodes and the second upper electrode exposed through the third opening.

The organic light-emitting display device may further include: a fourth gate electrode interposed between the first insulating layer and the first gate electrode and including a transparent conductive material; a fourth pixel electrode interposed between the first insulating layer and the first pixel electrode and including a transparent conductive material; and a fourth upper electrode interposed between the first insulating layer and the first upper electrode and including a transparent conductive material, wherein the fourth gate electrode, the fourth pixel electrode, and the fourth upper electrode include the same transparent conductive material, and the transparent conductive material includes at least one material selected from the group consisting of ITO, IZO, ZnO, In₂O₃, IGO, and AZO.

According to another aspect of the present embodiments, there is provided a method of manufacturing an organic light-emitting display device, the method including: a first mask process of forming a semiconductor layer on a substrate and patterning the semiconductor layer so as to form an active layer of a thin-film transistor (TFT) and a lower electrode of a capacitor; a second mask process of forming a first insulating layer on the substrate so as to cover the active layer and the lower electrode, sequentially stacking a first conductive layer including silver (Ag) or an Ag alloy, a second conductive layer including a transparent conductive material, and a third conductive layer including metal on the first insulating layer and then patterning the first conductive layer, the second conductive layer, and the third conductive layer so as to form a plurality of pixel electrodes including a first electrode, a second electrode, and a third electrode sequentially stacked in the order stated, a gate electrode of the TFT including a first gate electrode, a second gate electrode, and a third gate electrode sequentially stacked in the order stated, and an upper electrode of the capacitor including a first upper electrode, a second upper electrode, and a third upper electrode sequentially stacked in the order stated; a third mask process of forming a second insulating layer on the first insulating layer so as to cover the pixel electrodes, the gate electrode, and the upper electrode and patterning the second insulating layer so as to form a fist opening and a second opening for exposing the third pixel electrode, a contact hole for exposing source and drain regions of the active layer, and a third opening for exposing the third upper electrode; a fourth mask process of forming a fourth conductive layer on the second insulating layer so as to cover portions exposed through the first through third openings and the contact hole and patterning the fourth conductive layer so as to form source and drain electrodes; and a fifth mask process of forming a third insulating layer on the second insulating layer so as to cover the source and drain electrodes and patterning the third insulating layer so as to form a fourth opening for exposing the pixel electrodes.

The method may further include, after the second mask process is performed, doping ion impurities in the source and drain regions by using the first through third gate electrodes as a mask.

The fourth mask process may include removing portions of the third pixel electrode exposed through the first opening and the third upper electrode exposed through the third opening.

The method may further include, after the fourth mask process is performed, doping impurity ions from the second upper electrode exposed through the third opening in the lower electrode.

The first conductive layer may include a structure in which a first metal layer, a transparent conductive layer, and a second metal layer are sequentially stacked in the order stated, and at least one of the first metal layer and the second metal may include Ag or an Ag alloy.

Thicknesses of the first metal layer and the second metal layer may be respectively between about 20 Å and 130 Å.

A sum of the thicknesses of the first metal layer and the second metal layer may be between about 100 Å and 200 Å.

The second conductive layer may include at least one material selected from the group consisting of an indium tin oxide (ITO), an indium zinc oxide (IZO), a zinc oxide (ZnO), an indium oxide (In₂O₃), an indium gallium oxide (IGO), and an aluminum zinc oxide (AZO).

The third conductive layer may include at least one metal selected from the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The method may further include, after interposing a fourth conductive layer including a transparent conductive material between the first insulating layer and the first conductive layer, simultaneously patterning the first through third conductive layers so that a fourth pixel electrode is able to be interposed between the first insulating layer and the first pixel electrode, a fourth gate electrode is able to be interposed between the first insulating layer and the first gate electrode and a fourth upper electrode is able to be interposed between the first insulating layer and the first upper electrode, wherein the transparent conductive material includes at least one material selected from the group consisting of ITO, IZO, ZnO, In₂O₃, IGO, and AZO.

### BRIEF DESCRIPTION OF THE DRAWINGS

The above and other features and advantages of the present embodiments will become more apparent by describing in detail example embodiments thereof with reference to the attached drawings in which:

FIGS. 1 through 17 are schematic cross-sectional views illustrating a method of manufacturing an organic light-emitting display device, according to an embodiment; and

FIG. 18 is a schematic cross-sectional view of an organic light-emitting display device manufactured by the method of manufacturing an organic light-emitting display device illustrated in FIGS. 1 through 17, according to an embodiment.

### DETAILED DESCRIPTION

The present embodiments will now be described more fully with reference to the accompanying drawings in which example embodiments are shown.

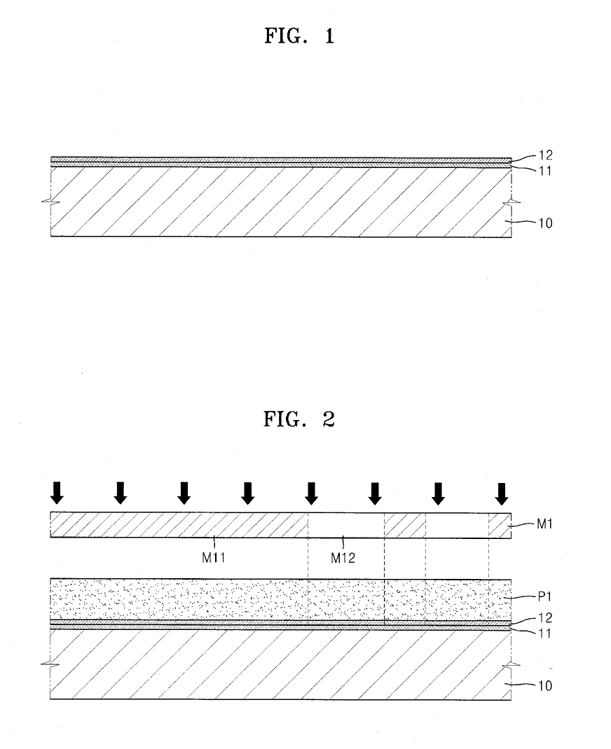

First, an organic light-emitting display device and a method of manufacturing the same, according to embodiments, will be described with reference to FIGS. 1 through 18.

FIGS. 1 through 17 are schematic cross-sectional views illustrating a method of manufacturing an organic light-emitting display device, according to an embodiment, and FIG. 18 is a schematic cross-sectional view of an organic light-emitting display device manufactured by the method of manufacturing an organic light-emitting display device illustrated in FIGS. 1 through 17, according to an embodiment.

Referring to FIG. 1, a buffer layer 11 and a semiconductor layer 12 are sequentially formed on a substrate 10 in the order stated.

The substrate 10 may comprise a transparent glass material containing SiO₂ as a main component. The buffer layer 11, including SiO₂ and/or SiNx, may be further formed on the substrate 10 so as to planarize the substrate 10 and to prevent impurity elements from penetrating into the substrate 10.

The buffer layer 11 and the semiconductor layer 12 may be deposited using various deposition methods, such as plasma enhanced chemical vapor deposition (PECVD), atmospheric pressure CVD (APCVD), and low pressure CVD (LPCVD).

The semiconductor layer 12 is deposited on the buffer layer 11. The semiconductor layer 12 may comprise amorphous silicon or polysilicon. In this regard, polysilicon may be formed by crystallizing amorphous silicon. Amorphous silicon may be crystallized using various methods, such as rapid thermal annealing (RTA), solid phase crystallization (SPC), excimer laser annealing (ELA), metal-induced crystallization (MIC), metal-induced lateral crystallization (MILC), and sequential lateral solidification (SLS).

Referring to FIG. 2, a first photoresist P1 is applied onto the semiconductor layer 12, and a first mask process is performed using a first photomask M1 including a light-blocking portion M11 and a light-transmission portion M12.

Although not shown in detail, after an exposure process is performed on the first photomask M1 by using an exposure device (not shown), a series of processes, such as developing, etching, stripping, ashing, and the like, are performed.

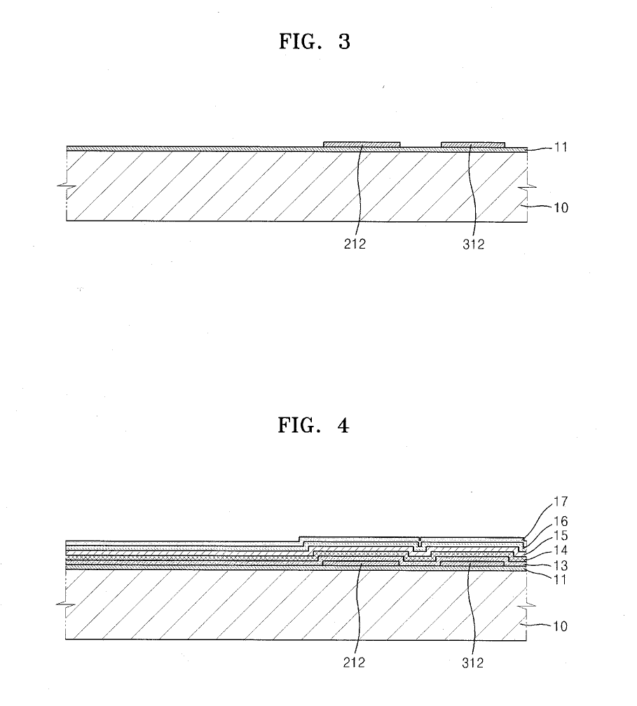

Referring to FIG. 3, as a result of the first photomask process, the semiconductor layer 12 is patterned as an active layer 212 of a thin-film transistor (TFT) and as a lower electrode 312 of a capacitor, wherein the lower electrode 312 is formed on the same layer as the active layer 212 and of the same material as the active layer 21.

Referring to FIG. 4, a first insulating layer 13, a first conductive layer 15, a second conductive layer 16, and a third conductive layer 17 are sequentially stacked on the resultant structure of FIG. 3 in the order stated.

The first insulating layer 13 may include a single layer or layers each comprising SiO₂ and/or SiNx and may function as a gate insulating layer of the TFT and a dielectric layer of the capacitor. The first insulating layer 13 may comprise various inorganic insulating materials and/or organic insulating materials, as well as SiO₂ and/or SiNx.

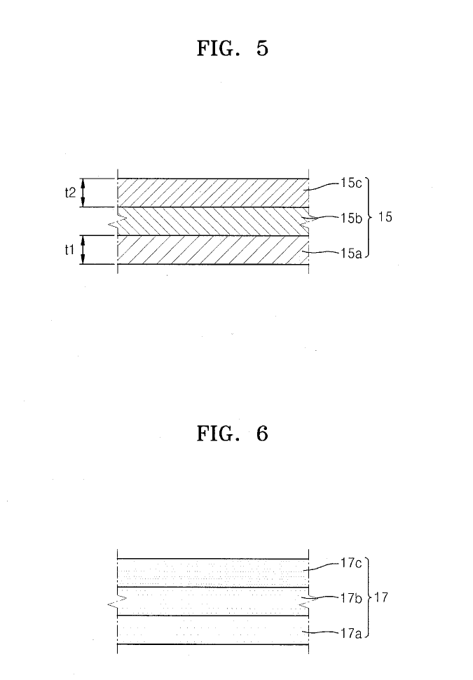

The first conductive layer 15 has a structure in which a first metal layer 15a, a transparent conductive layer 15b, and a second metal layer 15c are sequentially stacked in the order stated, as illustrated in FIG. 5.

At least one of the first metal layer 15a and the second metal layer 15c may comprise silver (Ag) or an Ag alloy. When one of the first metal layer 15a and the second metal layer 15c comprises Ag or an Ag alloy, the other one thereof may comprise an aluminum (Al) alloy. As will be described later, in order to realize a semi-transmission mirror with good efficiency, both the first metal layer 15a and the second metal layer 15c may comprise Ag or an Ag alloy having good light transmission and light reflection characteristics.

The transparent conductive layer 15b may comprise at least one material selected from the group consisting of an indium tin oxide (ITO), an indium zinc oxide (IZO), a zinc oxide (ZnO), an indium oxide (In₂O₃), an indium gallium oxide (IGO), and an aluminum zinc oxide (AZO).

The first metal layer 15a is formed to a first thickness t1, and the second metal layer 15c is formed to a second thickness t2. The first thickness t1 and the second thickness t2 may be between about 20 Å and 130 Å. When the first thickness t1 and the second thickness t2 are greater than 20 Å, the first conductive layer 15 may function as a reflective layer, and when the first thickness t1 and the second thickness t2 are less than 130 Å, etching characteristics of the first metal layer 15a and the second metal layer 15c may be obtained, and the first metal layer 15a and the second metal layer 15b may be etched simultaneously with the second conductive layer 16 and the third conductive layer 17.

The sum of the first thickness t1 and the second thickness t2 may be from about 100 to 200 Å.

The sum of the first thickness t1 and the second thickness t2 must be from about 100 to 200 Å so that the first conductive layer 15 may function as a reflective layer and light may transmit through the first conductive layer 15 and optical resonance may be achieved, as will be described later.

The second conductive layer 16 may comprise a transparent conductive material. In particular, the second conductive layer 16 comprises material having a high work function absolute value, so as to function as an anode electrode, as will be described later. For example, the second conductive layer 16 may comprise a transparent conductive material including at least one material selected from the group consisting of ITO, IZO, ZnO, In₂O₃, IGO, and AZO.

The third conductive layer 17 may include at least one metal selected from the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In the current embodiment, the third conductive layer 17 includes Al.

The third conductive layer 17 may include a plurality of layers, namely, metal layers 17a, 17b, 17c, as illustrated in FIG. 6. In the current embodiment, a three-layer structure (Mo/Al/Mo) is formed, wherein the Al layer 17b is interposed between Mo layers 17a and 17c. However, the present embodiments are not limited thereto. The third conductive layer 17 may comprise layers of various materials.

A fourth conductive layer 14 may be further interposed between the first insulating layer 13 and the first conductive layer 15. The fourth conductive layer 14 may be used to increase an adhesive force so that the first conductive layer 15, the second conductive layer 16, and the third conductive layer 17 may be securely adhered to the third insulating layer 13.

The fourth conductive layer 14 may comprise a transparent conductive material. For example, the fourth conductive layer 14 may comprise at least one material selected from the group consisting of ITO, IZO, ZnO, In₂O₃, IGO, and AZO.

In the following embodiments, the fourth conductive layer 14 is included. However, the present embodiments are not limited thereto, and the fourth conductive layer 14 may not be included.

As described above, since the first conductive layer 15, which is a semi-transmission reflective layer, includes the first metal layer 15a and the second metal layer 15c respectively comprising Ag or an Ag alloy, as illustrated in FIG. 5, the high efficiency of semi-transmission reflection of Ag may be used, and simultaneously, a stack structure of the first conductive layer 15 through the third conductive layer 17, and furthermore, a stack structure of the fourth conductive layer 14 through the third conductive layer 17 may be simultaneously patterned. As a result, an etching surface of sides of the first conductive layer 15 through the third conductive layer 17 is identical with an etching surface of sides of the fourth conductive layer 14 through the third conductive layer 17.

The stack structure of the first conductive layer 15 through the third conductive layer 17 or the stack structure of the fourth conductive layer 14 through the third conductive layer 17 may be simultaneously etched using a single etchant and may be patterned so that the performance of the method of manufacturing the organic light-emitting display device may be further improved.

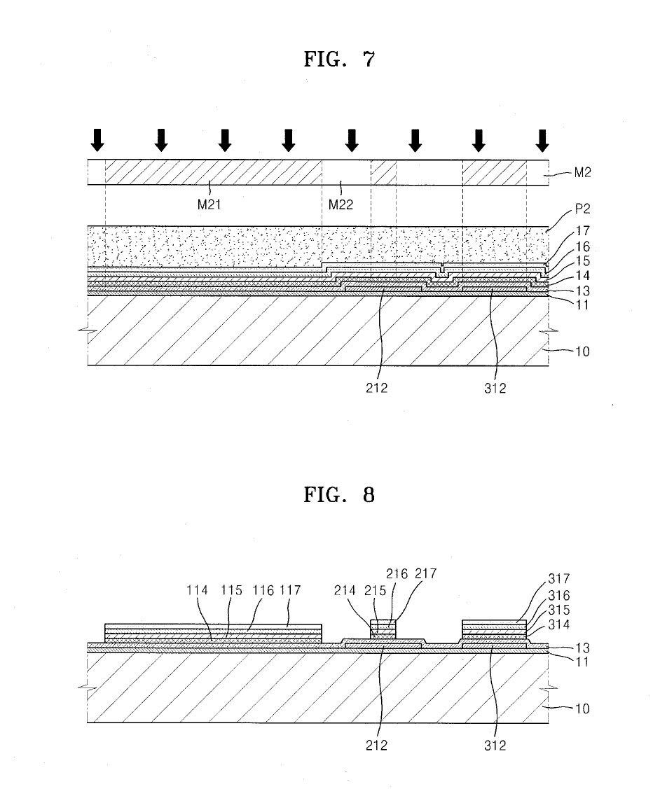

Referring to FIG. 7, a second photoresist P2 is applied onto the third conductive layer 17, and a second mask process is performed using a second photomask M2 including a light-blocking portion M21 and a light-transmission portion M22.

Referring to FIG. 8, as a result of the second mask process, the stack structure of the fourth conductive layer 14 through the third conductive layer 17 is patterned as a stack structure of a fourth pixel electrode 114 through a third pixel electrode 117, a stack structure of a fourth gate electrode 214 through a third gate electrode 217 of a TFT, and a stack structure of a fourth upper electrode 314 through a third upper electrode 317 of the capacitor. In detail, the fourth conductive layer 14 is patterned as the fourth pixel electrode 114, the fourth gate electrode 214, and the fourth upper electrode 314. The first conductive layer 15 is patterned as a first pixel electrode 115, a first gate electrode 215, and a first upper electrode 315. The second conductive layer 16 is patterned as a second pixel electrode 116, a second gate electrode 216, and a second upper electrode 316. The third conductive layer 17 is patterned as the third pixel electrode 117, the third gate electrode 217, and the third upper electrode 317.

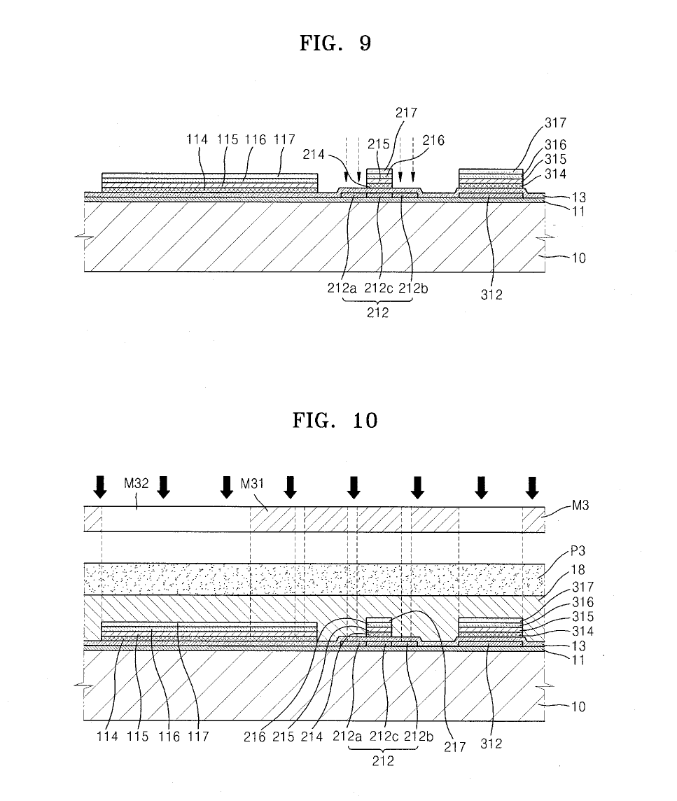

Referring to FIG. 9, by using a stack structure of the fourth gate electrode 214 through the third gate electrode 217 formed as a result of the second mask process as a self alignment mask, ion impurities are doped into the active layer 212. As a result, the active layer 212 includes source and drain regions 212a and 212b in which ion impurities are doped, and a channel region 212c interposed therebetween. As such, the source and drain regions 212a and 212b may be formed without an additional photomask.

Referring to FIG. 10, a second insulating layer 18 and a third photoresist P3 are applied onto a structure of the second mask process, and a third mask process is performed using a third photomask M3 including a light-blocking portion M31 and a light-transmission portion M32.

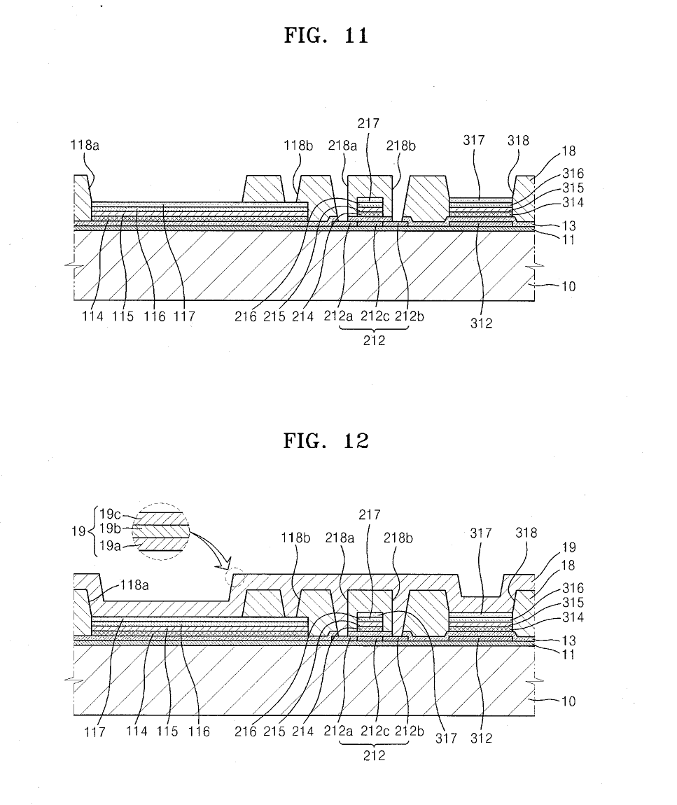

Referring to FIG. 11, as a result of the third mask process, a first opening 118a and a second opening 118b for opening portions of the third pixel electrode 117, contact holes 218a and 218b for exposing the source and drain regions 212a and 212b of the TFT, and a third opening 318 for opening the third upper electrode 317 of the capacitor are formed in the second insulating layer 18.

Referring to FIG. 12, a fifth conductive layer 19 is formed on a structure of FIG. 10.

The fifth conductive layer 19 may include at least one metal selected from the group consisting of Al, Pt, Pd, Ag, Mg, Au, Ni, Nd, Ir, Cr, Li, Ca, Mo, Ti, W, and Cu. In the current embodiment, the fifth conductive layer 19 includes Al.

In addition, the fifth conductive layer 19 may include multiple metal layers 19a, 19b, and 19c. In the current embodiment, a three-layer structure (Mo/Al/Mo) in which an Al layer 19b is interposed between Mo layers 19a and 19c, is employed, like in the third conductive layer 17. However, the present embodiments are not limited thereto. The fifth conductive layer 19 may comprise layers of various materials. For example, the fifth conductive layer 19 may be formed as a structure of Ti/Al/Ti.

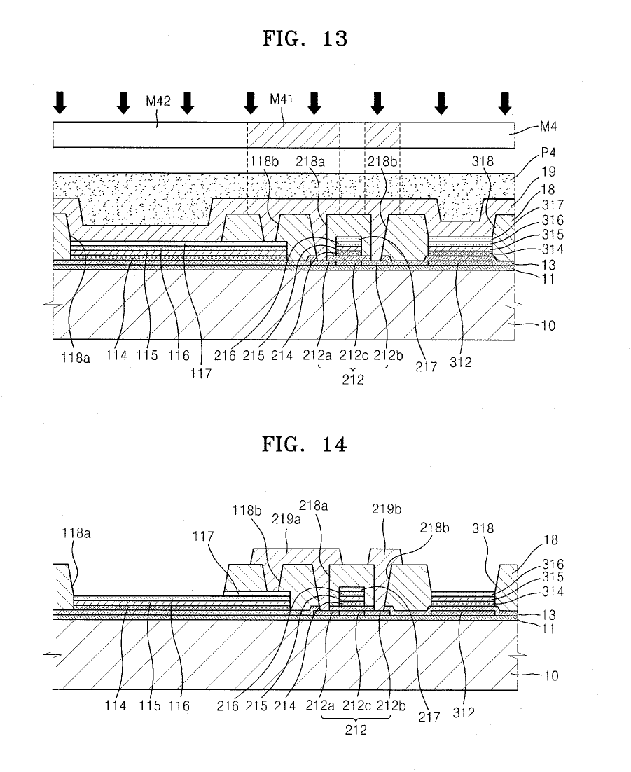

Referring to FIG. 13, a fourth photoresist P4 is applied onto the fifth conductive layer 19, and a fourth mask process is performed using a fourth photomask M4 including a light-blocking portion M41 and a light-transmission portion M42.

Now, the fifth conductive layer 19 is patterned using the fourth mask process. Layers formed as the third conductive layer 17 formed below the fifth conductive layer 19 may be simultaneously patterned when the first conductive layer 15 is etched.

In detail, referring to FIGS. 13 and 14, when source and drain electrodes 219a and 219b that are electrically connected to the source and drain regions 212a and 212b are formed by patterning the fourth conductive layer 19, portions of the third pixel electrode 117 exposed through the first opening 118a and the third upper electrode 317 exposed through the third opening 318 are simultaneously etched and removed. Thus, the second pixel electrode 116 and the second upper electrode 316 are exposed through the first opening 118a and the third opening 318, as illustrated in FIG. 14.

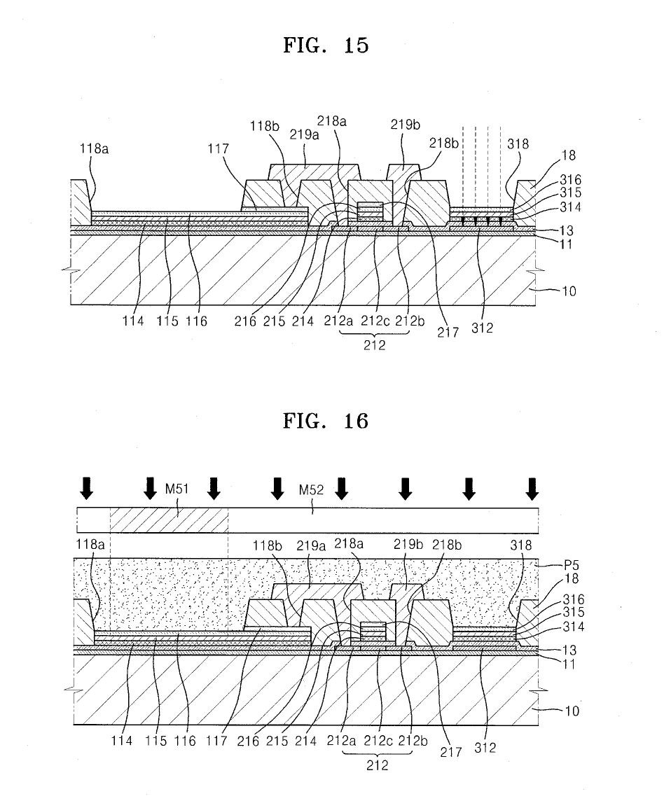

Referring to FIG. 15, ion impurities are doped from the structure as a result of the fourth mask process. When the ion impurities are doped, B or P ions are doped at a concentration that is greater than about 1×10¹⁵ atoms/cm², and the lower electrode 312 of the capacitor formed as the semiconductor layer 12 is doped. As such, the lower electrode 312 of the capacitor has increased conductivity and thus forms a metal-insulator-metal (MIM) capacitor together with the fourth upper electrode 314, the first upper electrode 315, and the second upper electrode 316, thereby increasing the capacity of the capacitor.

Referring to FIG. 16, a fifth photoresist P5 is applied onto a structure of FIG. 15, and a fifth mask process is performed using a fifth photomask M5 including a light-blocking portion M51 and a light-transmission portion M52.

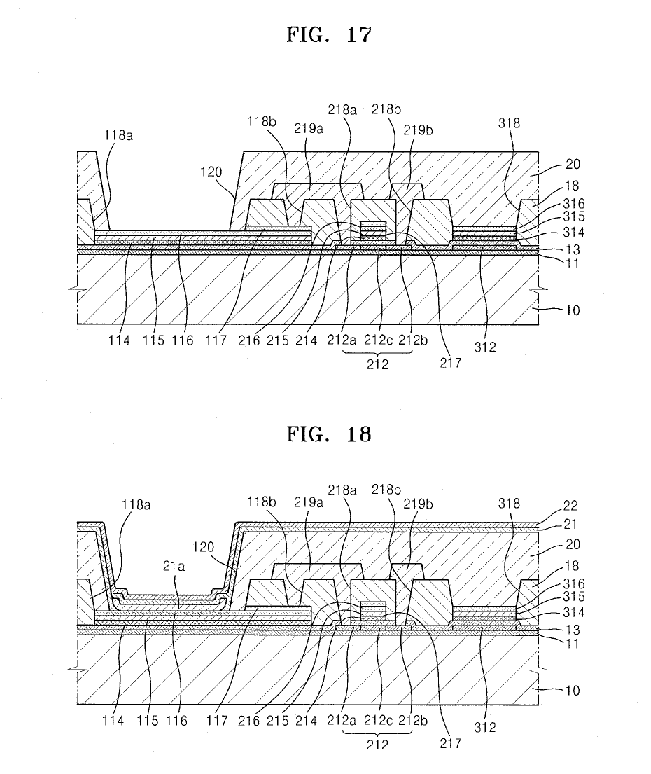

In this regard, the fourth mask process is performed in such a way that an exposure process is able to be performed on the fifth photomask M5 by using an exposure device (not shown) and then developing and ashing processes are able to be performed to form a fourth opening 120 through which the second pixel electrode 116 is exposed, and then to fire the fifth photoresist P5 so that the fifth photoresist P5 may be a third insulating layer 20, as illustrated in FIG. 17. However, the present embodiments are not limited thereto. After the third insulating layer 20 is formed using an organic and/or inorganic material, the fifth photoresist P5 is applied onto the third insulating layer 20, and the fourth opening 120 may be formed after a general mask process is performed.

Since the first pixel electrode 115 formed as the above-described first conductive layer 15 and including layers comprising Ag or an Ag alloy is formed under the second pixel electrode 116 exposed as described above, some of light may transmit through the first pixel electrode 115 and some of light may be reflected from the first pixel electrode 115. Due to the first pixel electrode 115 that is a semi-transmission mirror through which light transmits or from which light is reflected, an organic light-emitting display device using an optical resonance structure may be realized.

Referring to FIG. 18, an organic layer 21 including an organic emission layer 21 a and an opposite electrode 22 are formed above the second pixel electrode 116.

The organic emission layer 21 a may be a low-molecular weight organic layer or a polymer organic layer.

The organic layer 21 may be formed by stacking a hole transport layer (HTL) and a hole injection layer (HIL) in a direction toward the second pixel electrode 116 based on the organic emission layer 21a and by stacking an electron transport layer (ETL) and an electron injection layer (EIL) in a direction toward the opposite electrode 22 based on the organic emission layer 21a. In addition, the organic layer 21 may be formed by stacking various layers, if necessary.

Due to the organic layer 21 including the organic emission layer 21a, an optical resonance structure may be realized by making the thickness of the organic emission layer 21a or the thicknesses of other layers included in the organic layer 21 excluding the organic emission layer 21a different according to pixels.

The opposite electrode 22 as a common electrode is deposited on the organic layer 21. In the organic light-emitting display device according to the current embodiment, the fourth pixel electrode 114, the first pixel electrode 115, and the second pixel electrode 116 are used as an anode electrode, and the opposite electrode 22 is used as a cathode electrode. Obviously, polarities of the electrodes described above may be reverse.

In addition, the opposite electrode 22 may be a reflective electrode including a reflective material, so as to realize an optical resonance structure. In this regard, the opposite electrode 22 may comprise Al, Ag, Mg, Li, Ca, LiF/Ca or LiF/Al.

Although not shown, a sealant (not shown) for protecting the organic emission layer 21a from external moisture or oxygen and a moisture absorbent (not shown) may be further disposed on the opposite electrode 22.

According to the present embodiments, a distance between the opposite electrode 22 and the first pixel electrode 115 is formed as a resonance thickness so that, even in a bottom emission type in which an image is displayed in a direction toward the substrate 10, optical efficiency may be further improved using optical resonance.

In addition, the lower electrode 312 of the capacitor may comprise N+- or P+-doped polysilicon so that a capacitor having a MIM structure may be formed. When the capacitor has an MOS structure, since a high voltage must be continuously applied to a predetermined wire of a panel, a danger of an electrical short circuit is increased. However, according to the present embodiments, the MIM capacitor is realized as described above so that the problem may be prevented and a degree of freedom in design is improved. An organic light-emitting display device and a method of manufacturing the same according to the present embodiments provide the following effects.

Firstly, a pixel electrode has a semi-transmission mirror comprising Ag or an Ag alloy having good light transmission and reflection characteristics so that optical resonance may be realized in a bottom emission type in which an image is displayed in a direction toward the pixel electrode and optical efficiency may be further improved.

Secondly, when the semi-transmission mirror comprises Ag or an Ag alloy, the semi-transmission mirror is formed to include a first metal layer and a second metal layer so that, when patterning of the pixel electrode is performed, a transparent conductive layer or a gate electrode may not be damaged, a multiple stack structure of the pixel electrode may be patterned using a single process and the performance of a method of manufacturing the organic light-emitting display device may be further improved.

Thirdly, the organic light-emitting display device including the semi-transmission mirror may be manufactured by performing a mask process five times.

Fourthly, since a MIM capacitor structure may be formed using a simple process, not only the performance of the method of manufacturing the organic light-emitting display device but also a circuit characteristic may be further improved.

While the present embodiments have been particularly shown and described with reference to example embodiments thereof, it will be understood by those of ordinary skill in the art that various changes in form and details may be made therein without departing from the spirit and scope of the present embodiments as defined by the following claims.

What is claimed is:

1. An organic light-emitting display device comprising:
an active layer of a thin-film transistor (TFT) formed on a substrate and comprising a semiconductor material;
a lower electrode of a capacitor formed on the substrate and comprising a semiconductor material in which impurity ions are doped;
a first insulating layer formed on the substrate so as to cover the active layer and the lower electrode;
a gate electrode of the TFT formed on the first insulating layer and comprising a first gate electrode comprising silver (Ag) or an Ag alloy, a second gate electrode comprising a transparent conductive material, and a third gate electrode comprising metal that are sequentially stacked in the order stated;
a plurality of pixel electrodes formed on the first insulating layer and comprising a first pixel electrode comprising Ag or an Ag alloy and a second pixel electrode comprising a transparent conductive material that are sequentially stacked in the order stated;
an upper electrode of the capacitor formed on the first insulating layer and comprising a first upper electrode comprising Ag or an Ag alloy and a second upper electrode comprising a transparent conductive material that are sequentially stacked in the order stated;
source and drain electrodes of the TFT electrically connected to the active layer;
an organic layer disposed on the pixel electrode and comprising an organic emission layer; and
an opposite electrode disposed facing each of the pixel electrodes;
wherein the organic layer is interposed between the opposite electrode and each of the pixel electrodes.

2. The organic light-emitting display device of claim 1, wherein the first gate electrode, the first pixel electrode, and the first upper electrode comprise a structure in which a first metal layer, a transparent conductive layer, and a second metal layer are sequentially stacked in the order stated, and at least one of the first metal layer and the second metal layer comprises Ag or an Ag alloy.

3. The organic light-emitting display device of claim 2, wherein thicknesses of the first metal layer and the second metal layer are each between about 20 Å and about 130 Å.

4. The organic light-emitting display device of claim 2, wherein a sum of the thicknesses of the first metal layer and the second metal layer are between about 100 Å and about 200 Å.

5. The organic light-emitting display device of claim 1, wherein the second gate electrode, the second pixel electrode, and the second upper electrode comprise at least one material selected from the group consisting of an indium tin oxide (ITO), an indium zinc oxide (IZO), a zinc oxide (ZnO), an indium oxide (In₂O₃), an indium gallium oxide (IGO), and an aluminum zinc oxide (AZO).

6. The organic light-emitting display device of claim 1, further comprising:
a third pixel electrode stacked on the second pixel electrode and comprising metal; and
a second insulating layer formed on the first insulating layer so as to cover the third pixel electrode and the gate electrode and comprising a first opening for exposing portions of the second pixel electrode, a second opening for exposing portions of the third pixel electrode, and a third opening for exposing the second upper electrode,
wherein the source and drain electrodes are formed on the second insulating layer, and one of the source and drain electrodes contacts the third pixel electrode through the second opening.

7. The organic light-emitting display device of claim 6, wherein the third pixel electrode and the third gate electrode comprise the same metal, and the metal comprises at least one metal selected from the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

8. The organic light-emitting display device of claim 6, wherein the third pixel electrode and the third gate electrode comprise multiple metal layers.

9. The organic light-emitting display device of claim 1, wherein the first pixel electrode is a semi-transmission mirror through which some of light emitted from the organic emission layer transmits and from which some of light emitted from the organic emission layer is reflected.

10. The organic light-emitting display device of claim 1, wherein the opposite electrode is configured to reflect light emitted from the organic emission layer.

11. The organic light-emitting display device of claim 1, wherein an end of the first pixel electrode and an end of the second pixel electrode have a substantially identical etching surface.

12. The organic light-emitting display device of claim 6, further comprising a third insulating layer formed on the second insulating layer, wherein the third insulating layer comprises a fourth opening for exposing portions of the second pixel electrode exposed through the first opening and covers the source and drain electrodes and the second upper electrode exposed through the third opening.

13. The organic light-emitting display device of claim 1, further comprising:
a fourth gate electrode interposed between the first insulating layer and the first gate electrode and comprising a transparent conductive material;
a fourth pixel electrode interposed between the first insulating layer and the first pixel electrode and comprising a transparent conductive material; and
a fourth upper electrode interposed between the first insulating layer and the first upper electrode and comprising a transparent conductive material, wherein the fourth gate electrode, the fourth pixel electrode, and the fourth upper electrode comprise the same transparent conductive material, and the transparent conductive material comprises at least one material selected from the group consisting of ITO, IZO, ZnO, In₂O₃, IGO, and AZO.

14. A method of manufacturing an organic light-emitting display device, the method comprising:
performing a first mask process forming a semiconductor layer on a substrate and patterning the semiconductor layer so as to faun an active layer of a thin-film transistor (TFT) and a lower electrode of a capacitor;
performing a second mask process forming a first insulating layer on the substrate so as to cover the active layer and the lower electrode, sequentially stacking a first conductive layer comprising silver (Ag) or an Ag alloy, a second conductive layer comprising a transparent conductive material, and a third conductive layer comprising metal on the first insulating layer and then patterning the first conductive layer, the second conductive layer, and the third conductive layer so as to form a plurality of pixel electrodes comprising a first electrode, a second electrode, and a third electrode sequentially stacked in the order stated, a gate electrode of the TFT comprising a first gate electrode, a second gate electrode, and a third gate electrode sequentially stacked in the order stated, and an upper electrode of the capacitor comprising a first upper electrode, a second upper electrode, and a third upper electrode sequentially stacked in the order stated;
performing a third mask process forming a second insulating layer on the first insulating layer so as to cover the pixel electrodes, the gate electrode, and the upper electrode and patterning the second insulating layer so as to form a first opening and a second opening for exposing the third pixel electrode, a contact hole for exposing source and drain regions of the active layer, and a third opening for exposing the third upper electrode;
performing a fourth mask process forming a fourth conductive layer on the second insulating layer so as to cover portions exposed through the first through third openings and the contact hole and patterning the fourth conductive layer so as to form source and drain electrodes; and
performing a fifth mask process forming a third insulating layer on the second insulating layer so as to cover the source and drain electrodes and patterning the third insulating layer so as to form a fourth opening for exposing the pixel electrodes.

15. The method of claim 14, further comprising, after the second mask process is performed, doping ion impurities in the source and drain regions by using the first through third gate electrodes as a mask.

16. The method of claim 14, wherein the fourth mask process comprises removing portions of the third pixel electrode exposed through the first opening and the third upper electrode exposed through the third opening.

17. The method of claim 14, further comprising, after the fourth mask process is performed, doping impurity ions from the second upper electrode exposed through the third opening in the lower electrode.

18. The method of claim 14, wherein the first conductive layer comprises a structure in which a first metal layer, a transparent conductive layer, and a second metal layer are sequentially stacked in the order stated, and at least one of the first metal layer and the second metal comprises Ag or an Ag alloy.

19. The method of claim 18, wherein thicknesses of the first metal layer and the second metal layer are respectively between about 20 Å and 130 Å.

20. The method of claim 18, wherein a sum of the thicknesses of the first metal layer and the second metal layer are between about 100 Å and 200 Å.

21. The method of claim 14, wherein the second conductive layer comprises at least one material selected from the group consisting of an indium tin oxide (ITO), an indium zinc oxide (IZO), a zinc oxide (ZnO), an indium oxide (In₂O₃), an indium gallium oxide (IGO), and an aluminum zinc oxide (AZO).

22. The method of claim 14, wherein the third conductive layer comprises at least one metal selected from the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

23. The method of claim 14, further comprising, after interposing a fourth conductive layer comprising a transparent conductive material between the first insulating layer and the first conductive layer, simultaneously patterning the first through third conductive layers so that a fourth pixel electrode is able to be interposed between the first insulating layer and the first pixel electrode, a fourth gate electrode is able to be interposed between the first insulating layer and the first gate electrode and a fourth upper electrode is able to be interposed between the first insulating layer and the first upper electrode, wherein the transparent conductive material comprises at least one material selected from the group consisting of ITO, IZO, ZnO, In₂O₃, IGO, and AZO.
